(19) United States
(12) Patent Application Publication
(10) Pub. No.: US 2010/0020515 A1
(43) Pub. Date: Jan. 28, 2010

(54) METHOD AND SYSTEM FOR MANUFACTURING MICRO SOLID STATE DRIVE DEVICES

(75) Inventors: Michael Rubino, San Jose, CA (US); Satyanarayan Shivkumar Iyer, Fremont, CA (US); Alessandro Fin, Los Gatos, CA (US); Mark E. Allen, Marlborough, MA (US); Phillip Henry Kaminski, Manchester, NH (US)

Correspondence Address: DLA PIPER LLP (US ), 2000 UNIVERSITY AVENUE, EAST PALO ALTO, CA, 94303-2248, US

(73) Assignee: Smart Modular Technologies, Inc., Fremont, CA (US)

(21) Appl. No.: 12/497,484

(22) Filed: Jul. 2, 2009

Related U.S. Application Data
(63) Continuation-in-part of application No. 12/013,903, filed on Jan. 14, 2008.
Application No. 12/013,903 is a continuation of application No. 11/075,641, filed on Mar. 8, 2005, now abandoned.
Application No. 11/075,641 is a continuation of application No. 11/075,576, filed on Mar. 8, 2005, now abandoned.

(51) Int. Cl. H05K 1/11

(52) U.S. Cl. 361/803

(57) ABSTRACT

A method of manufacturing a stacked module is disclosed and in particular a micro solid state device (MSSD).

### PRIORITY CLAIM/RELATED APPLICATIONS

This application is a continuation in part of and claims priority under 35 USC 120 to U.S. patent application Ser. No. 12/013,903 filed on Jan. 14, 2008 which in turns claims priority under 35 USC 120 to U.S. patent application Ser. No. 11/075,641 filed on Mar. 8, 2005 and Ser. No. 11/075,576 filed on Mar. 8, 2005, all of which are incorporated herein by reference.

### FIELD

The disclosure generally relates to integrated circuits, and in particular to methods and systems for manufacturing and packaging stacked memory modules using flexible circuits.

### BACKGROUND

There is an ever increasing need to minimize the footprint of integrated circuit devices. As form factor decreases, the area available for integrated circuit mounting also decreases. One currently popular approach that is used to address the foregoing problem is to stack multiple integrated circuits atop of each other. However, each of the integrated circuits still requires electrical connections to its electrical contacts. As a result, all the stacked integrated circuits also need to be electrically connected to the outside world. A number of prior art methods have been proposed and used to address the issue concerning electrical connections in stacked integrated circuits. These methods continue to have a number of shortcomings including, for example, high cost and complexity, physical constraints, and other technical issues, etc.

There are various types of integrated circuit devices providing different functionality. One type of integrated circuit device is dynamic random access memory (DRAM). As the DRAM industry migrates to the use of Chip-Scale-Packaged (CSP) devices, the number of DRAM devices that can be placed on a standard form factor module is constrained by the size of the device itself. This is due to the fact that the size of the CSP DRAM device tracks the size of the DRAM chip. For example, a 1 Gb CSP DRAM devices do not completely fit into the same standard form factor module as the 512 Mb CSP DRAM devices. The foregoing problem with respect to physical constraint was not present in the previous generation of TSOP (Thin Small Outline Packaging) where every device density would fit into a standard 400-mil package width.

Naturally, over time the size of the higher density device may eventually be reduced through die shrinks, allowing the desired number of components to fit within a standard form factor module. However, many applications may require a higher device density long before the desired die shrinks can be achieved. Even if and when the required die size reduction is achieved, there is likely to be a significant price premium associated with the higher density device for an extended period of time.

Hence, it would be desirable to provide methods and systems that are capable of more efficiently providing stacked integrated circuits.

### BRIEF DESCRIPTION OF THE DRAWINGS

FIG. 1 illustrates an example of a method for manufacturing a stacked device;

FIGS. 2A and 2B are a top view and side view, respectively, of an example of a first embodiment of a micro solid state drive device;

FIGS. 3A and 3B are a top view and side view, respectively, of an example of a second embodiment of a micro solid state drive device;

FIGS. 4A and 4B are a top view and side view, respectively, of an example of a third embodiment of a micro solid state drive device; and

FIGS. 5A and 5B illustrates another embodiment of micro solid state drive device in an unfolded state and folded state, respectively.

### DETAILED DESCRIPTION OF ONE OR MORE EMBODIMENTS

The system and method are particularly applicable to the production of a micro solid state device as illustrated below and it is in this context that the system and method will be described. It will be appreciated, however, that the system and method has greater utility since it can be used to produce other micro solid state devices with other configurations.

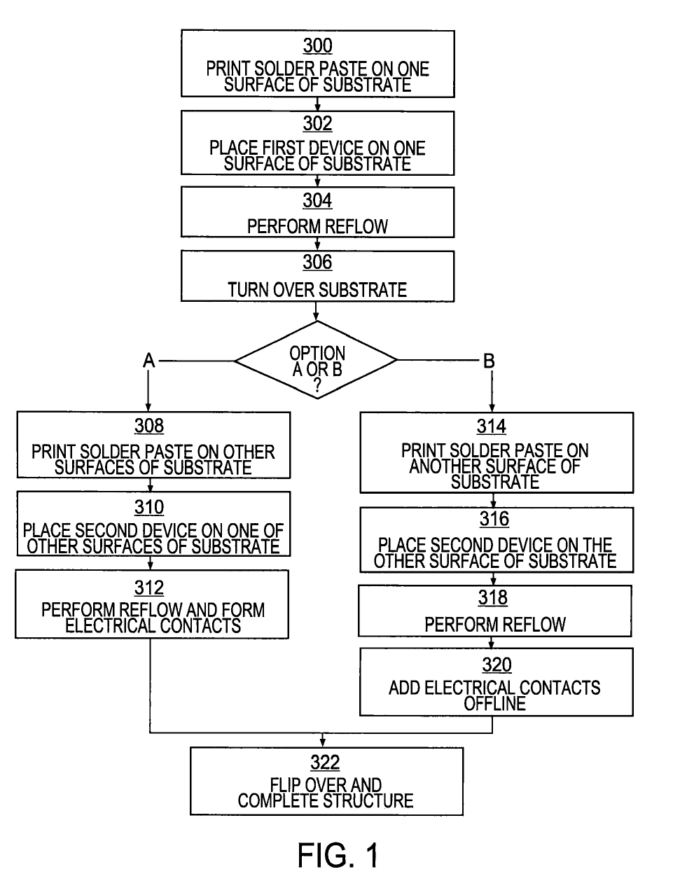

FIG. 1 illustrates an example of a method 300 for manufacturing a stacked device in which solder paste is printed on one surface of a substrate. Then, a first device is placed onto one surface of the substrate (302) and reflow is performed (304). Then, the substrate is turned over (306) and either option A or B is performed. For option A, solder paste is printed on the other surfaces of the substrate (308) and then place a device on one of the other surfaces of the substrate (310) and then reflow is performed to form electrical contacts (312) and then the device is flipped over and completed (322). For option B, solder paste is printed on another surface of the substrate (314), a memory device is placed on the other surface of the substrate (316), reflow is performed (318), electrical contacts are added (320) and then the device is flipped over and completed (322). Further details of the above manufacturing process is provided in co-pending, commonly owned patent application Ser. Nos. 11/075,641 and 11/075,576 that are incorporated herein by reference.

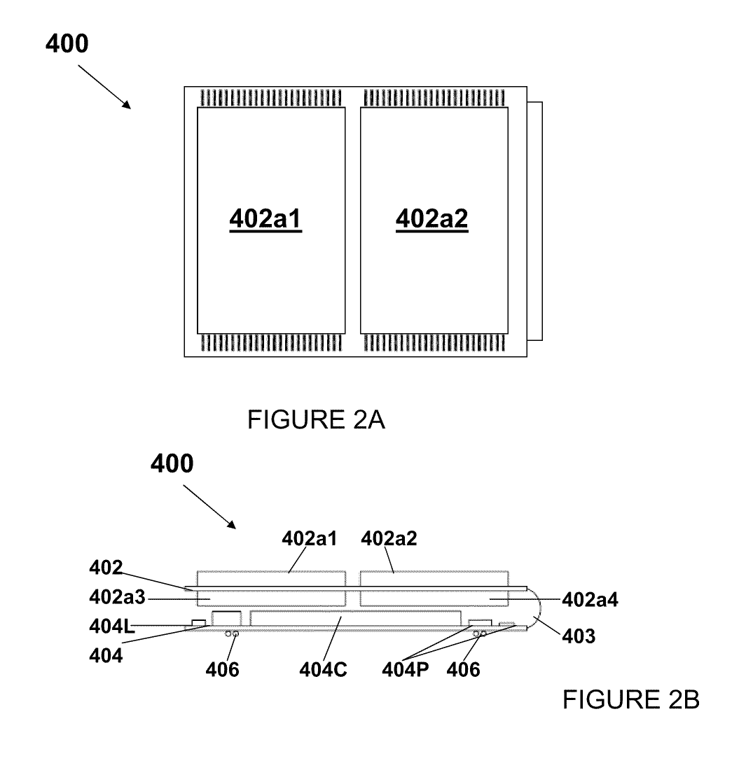

The method of manufacturing a stacked device described above can be used to manufacture high density memory devices/sub-assemblies. An example of one such application is the Micro Solid State Drive (MSSD). Examples of several embodiments of an MSSD that can be manufactured using the stacked device process are shown in FIGS. 2A-4B and are described below in more detail.

The MSSD is a reduced footprint device that can be soldered directly on the host board or used as a building block to instrument a multiple-channel mass storage device. The MSSD may include a memory controller that handles the translation between the host interface and the non-volatile memory interface. The MSSD is very flexible in terms of supported interfaces as it can support numerous interfaces, including but not limited to USB 1.0 & 2.0, parallel ATA, serial ATA 1.0 & 2.0, SAS, PCI express, SD 1.0 & 2.0, MMC, and/or a non-volatile memory type interface. The MSSD is operative system agnostic and it can be used with any OS supporting the selected host interface. In one exemplary application, the MSSD can be used both as an Operating System booting device as well as to store application data.

In general, the MSSD stacked device can be composed of one or more memory devices and/or controller or logic components. Either one or both sides of the substrate used for stacking can be populated with these components. The MSSD stacked device assembly can also contain additional active and passive components to support the functionality of the MSSD stacked device. The components used for stacking purposes can be of various form factors including a thin small outline package (TSOP), a leadless package (a land grid array package or a quad flat no-lead package), a chip on board package, a quad flat pak (QFP) package, a ball grid array (BGA) package and a chip scale packaging (CSP) package.

The benefits of the MSSD stacked device may include proven reliability and ruggedness; ease of manufacturability as it utilizes regular surface mount technology (SMT) equipment; a lower number of reflows when all the devices are populated on the same side of substrate used for stacking which minimizes the impact on the devices; and/or the solder balls required for interconnection between the stacked device and the host board can be formed using a ball attach method or by using a cost effective method of printing solder paste. Now, several embodiments of the MSSD stacked device are described in more detail.

FIGS. 2A and 2B are a top view and side view, respectively, of an example of a first embodiment of a micro solid state drive device 400. The MSSD may have a first and second substrate 402, 404 that are electrically connected to each other by a flexible circuit 403. Each substrate may have one or more components (memory components, logic components, controller(s) and/or active or passive components) that may be on one or both sides of the substrate. In the example shown in FIGS. 2A and 2B, the first substrate 402 may have one or more memory components (402a1, 402a2, 402a3 and 402a4 in the example shown) attached to each side of the substrate as shown. In the example shown, components may be placed only on one side of the second substrate 404 and the components may include one or more controller components 404c, one or more logic components 4041 and one or more active/passive components 404p. The bottom side of the second substrate 404 may have one or more solder bumps/solder balls 406 that allow the device to be mounted on a printed circuit board.

For example, an MSSD device may use a Parallel ATA host interface and include two Flash memory chips and one dual channel Flash memory controller. The MSSD device also may include one voltage regulator device to stabilize the voltage supply to the Flash memory controller and the Flash memory chips, one voltage detector device to improve the reliability of the MSSD during sub-optimal power supply and a few passive components to properly implement the host-MSSD interface from both the electrical and logical standpoint.

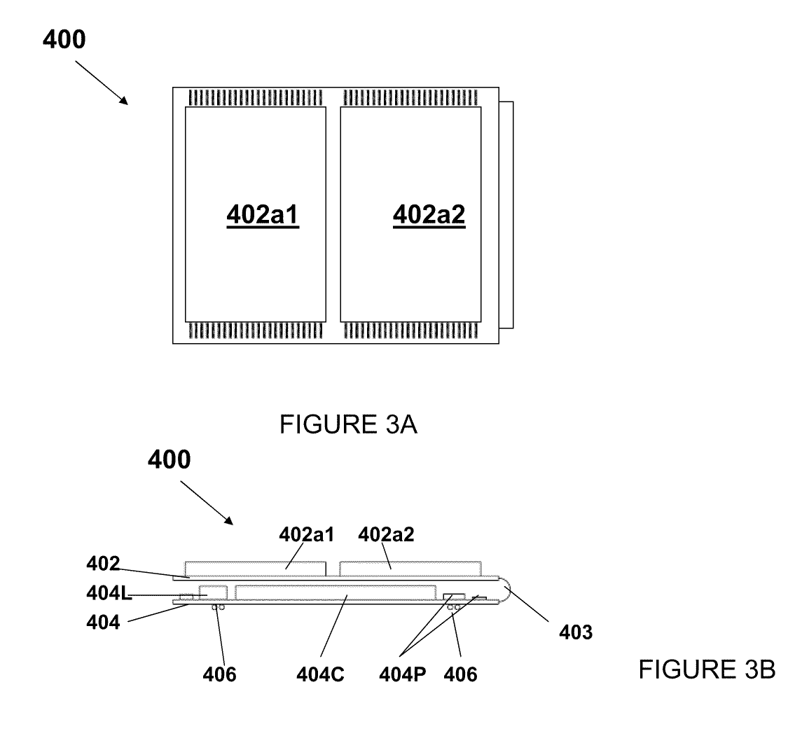

FIGS. 3A and 3B are a top view and side view, respectively, of an example of a second embodiment of a micro solid state drive device 400. The MSSD may have a first and second substrate 402, 404 that are electrically connected to each other by a flexible circuit 403. Each substrate may have one or more components (memory components, logic components, controller(s) and/or active or passive components) that may be on one or both sides of the substrate. In the example shown in FIGS. 3A and 3B, the first substrate 402 may have one or more memory components (402a1, 402a2 in the example shown) attached to one side of the substrate as shown. In the example shown, components may be placed only on one side of the second substrate 404 and the components may include one or more controller components 404c, one or more logic components 4041 and one or more active/passive components 404p. The bottom side of the second substrate 404 may have one or more solder bumps/solder balls 406 that allow the device to be mounted on a printed circuit board.

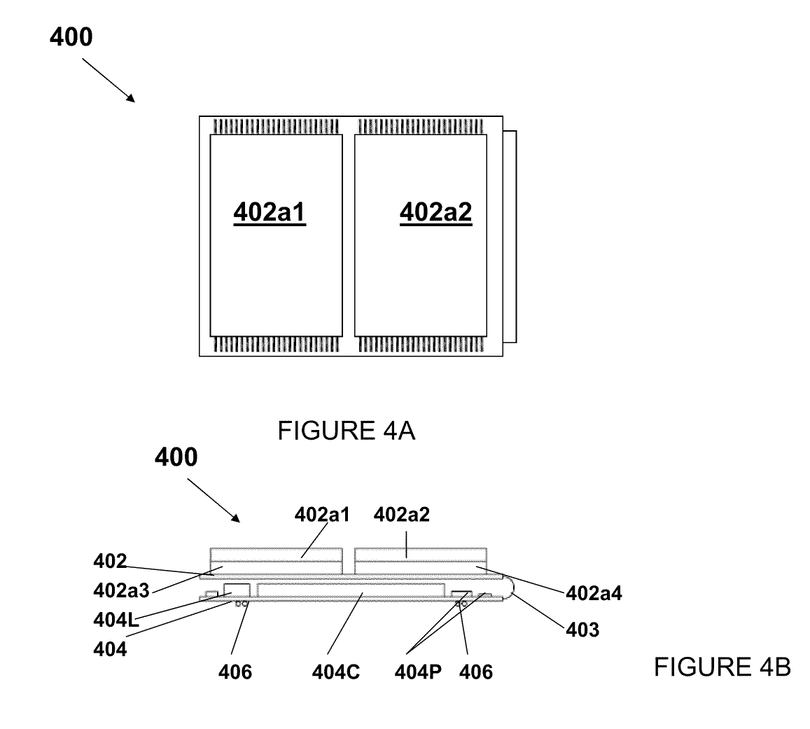

FIGS. 4A and 4B are a top view and side view, respectively, of an example of a third embodiment of a micro solid state drive device 400. The MSSD may have a first and second substrate 402, 404 that are electrically connected to each other by a flexible circuit 403. Each substrate may have one or more components (memory components, logic components, controller(s) and/or active or passive components) that may be on one or both sides of the substrate. In the example shown in FIGS. 4A and 4B, the first substrate 402 may have one or more memory components (402a1, 402a2, 402a3, 402a4 in the example shown) stacked on top of each other and attached to one side of the substrate as shown. In the example shown, components may be placed only on one side of the second substrate 404 and the components may include one or more controller components 404c, one or more logic components 4041 and one or more active/passive components 404p. The bottom side of the second substrate 404 may have one or more solder bumps/solder balls 406 that allow the device to be mounted on a printed circuit board.

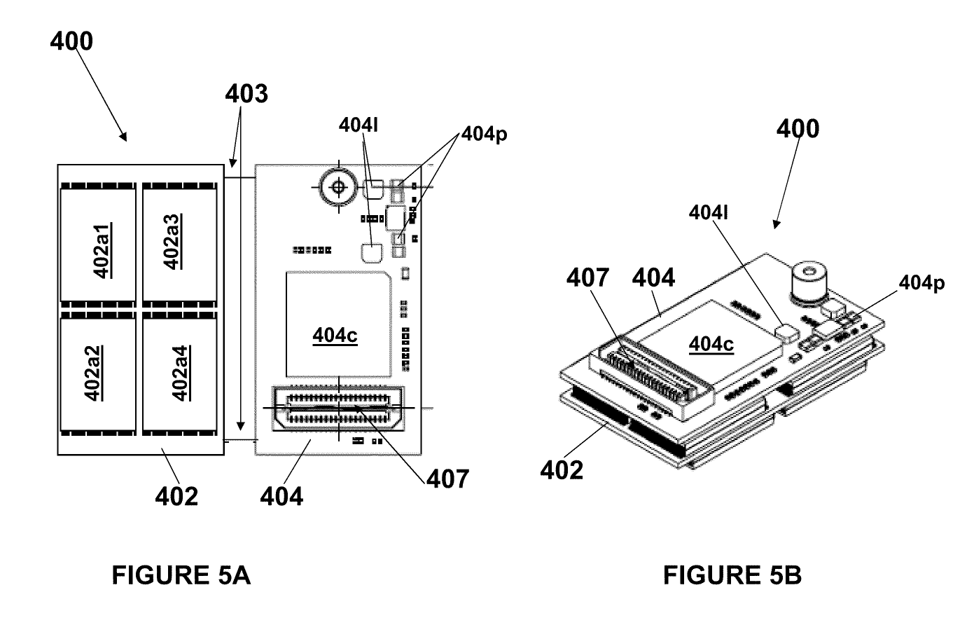

FIGS. 5A and 5B illustrates another embodiment of micro solid state drive device 400 in an unfolded state and folded state, respectively. In particular, FIG. 5A illustrates the device in an unstacked/unfolded state in which the first substrate 402 and the second substrate 404 are adjacent each other while FIG. 5B illustrates the device in the stacked/folded state in which the first substrate 402 and the second substrate 404 are folded/stacked on top of each other. As with the other embodiments, the MSSD may have the first and second substrate 402, 404 that are electrically connected to each other by a flexible circuit 403 wherein the flexible circuit may be a flexible printed circuit board and may have electrical traces that connect the first and second substrate 402, 404 to each other so that the MSSD may be formed as a single device having the rigid first and second substrates 402, 404 as well as the flexible circuit 403. Each substrate 402, 404 may have one or more components (memory components, logic components, controller(s) and/or active or passive components) that may be on one or both sides of each substrate. The components may be mounted on the substrates 402, 404 using the surface mount and reflow process as described above.

In the example shown in FIGS. 5A and 5B, the first substrate 402 may have one or more memory components/devices (402a1, 402a2, 402a3, 402a4 in the example shown) stacked on top of each other and attached to one side or both sides of the substrate 402. In the example shown, components may be placed only on one side of the second substrate 404 and the components may include one or more controller components 404c, one or more logic components 4041 and one or more active/passive components 404p. Additionally, the memory components 402, one or more controller components 404c, one or more logic components 4041 and one or more active/passive components 404p may also be mounted/placed on either surface of the second substrate or on either surface of the first substrate. In the example shown in FIGS. 5A and 5B, the second substrate 404 may also have a connector 407 mounted on the same side of the second substrate as the components as shown (or on the other side of the second substrate 404) that allows the MSSD device 400 to be mounted on and electrically and physically connected to a printed circuit board so that the MSSD is connectable to a main printed circuit board using the connector 407 that may be a industry standard connector. The connector 407 may also be located on either surface of the second substrate or on either surface of the first substrate.

The foregoing description of the embodiments of the invention has been presented for the purposes of illustration and description. It is not intended to be exhaustive or to limit the invention to the precise form disclosed. Many modifications and variations are possible in light of the above teaching. It is intended that the scope of the invention not be limited by this detailed description, but by the claims and the equivalents to the claims appended hereto.

1. A stacked device, comprising:
a first substrate;
a second substrate electrically connected to the first substrate by a flexible circuit wherein the second substrate is located vertically below the first substrate;
one or more memory devices mounted on a surface of one of the first substrate and the second substrate;
one or more controller components mounted on a surface of one of the first substrate and the second substrate; and
a mechanism, mounted on a surface of one of the first substrate and the second substrate, that is capable of mounting the stacked device onto a printed circuit board.

2. The device of claim 1, wherein one of the first substrate and the second substrate has one or more memory devices attached to each side of one of the first substrate and the second substrate.

3. The device of claim 1, wherein the first substrate has a first memory device attached to the substrate and a second memory device stacked on top of the first memory device.

4. The device of claim 1, wherein the one or more controller components and the one or more logic components are connected to a first side of the second substrate.

5. The device of claim 1, wherein the mechanism further comprises a plurality of solder balls attached to the second substrate.

6. The device of claim 1, wherein the mechanism further comprises a connector.

7. The device of claim 1, wherein each controller component has a package selected from the group consisting of: a thin small outline package, a leadless package, a chip on board package, a quad flat pack package, a ball grid array package and a chip scale packaging package.

8. The device of claim 7, wherein the leadless package further comprises one of a land grid array package and a quad flat no-lead package.

9. The device of claim 4, wherein each logic component has a package selected from the group consisting of: a thin small outline package, a leadless package, a chip on board package, a quad flat pack package, a ball grid array package and a chip scale packaging package.

10. The device of claim 9, wherein the leadless package further comprises one of a land grid array package and a quad flat no-lead package.

11. The device of claim 1, wherein each memory device has a package selected from the group consisting of: a thin small outline package, a leadless package, a chip on board package, a quad flat pack package, a ball grid array package and a chip scale packaging package.

12. The device of claim 11, wherein the leadless package further comprises one of a land grid array package and a quad flat no-lead package.

13. The device of claim 1, wherein the one or more memory devices further comprise a first memory device and a second memory device stacked on top of the first memory device.

14. The device of claim 1, wherein the one or more memory devices are surface mounted on one of the first substrate and the second substrate.

15. The device of claim 1, wherein the one or more controller components and one or more logic components are surface mounted on one of the first substrate and the second substrate.

16. The device of claim 1, wherein the flexible circuit further comprises a flexible printed circuit board.

17. The device of claim 1 further comprising one or more logic components mounted on a surface of one of the first substrate and the second substrate.
